(19) United States
(12) Patent Application Publication
(10) Pub. No.: US 2024/0404795 A1
(43) Pub. Date: Dec. 5, 2024

(54) SUBSTRATE-PROCESSING METHOD AND SUBSTRATE-PROCESSING APPARATUS

(71) Applicant: Tokyo Electron Limited, Tokyo (JP)

(72) Inventor: Hitoshi KATO, Iwate (JP)

(21) Appl. No.: 18/665,854

(22) Filed: May 16, 2024

(30) Foreign Application Priority Data
May 30, 2023 (JP) 2023-088839

(51) Int. Cl. H01J 37/32; C23C 16/455; C23C 16/458; C23C 16/52; H01L 21/02

(52) U.S. Cl. CPC H01J 37/32449; C23C 16/45544; C23C 16/45563; C23C 16/4584; C23C 16/52; H01J 37/32715; H01J 2237/20214; H01J 2237/332; H01L 21/02164

(57) ABSTRACT

A substrate-processing method for processing a substrate includes (A) holding the substrate by a substrate holder in a process chamber and rotating the substrate, (B) discharging gas from a discharge hole of a nozzle gas discharge mechanism toward the substrate held by the substrate holder, and (C) moving the nozzle gas discharge mechanism relative to the substrate in a direction parallel to a surface of the substrate held by the substrate holder so that the discharge hole passes over a center of the substrate. In (C), a speed of a relative movement of the nozzle gas discharge mechanism is changed in accordance with a surface area of a section of the substrate, the section being faced by the discharge hole.

### CROSS-REFERENCE TO RELATED APPLICATIONS

This application is based upon and claims priority to Japanese Patent Application No. 2023-088839, filed on May 30, 2023, the entire contents of which are incorporated herein by reference.

### BACKGROUND

### 1. Field of the Invention

The present disclosure relates to substrate-processing methods and substrate-processing apparatuses.

### 2. Description of the Related Art

Known substrate-processing apparatuses are configured to revolve multiple wafers (substrates) held on a susceptor and supplying multiple types of process gases from above the substrates, thereby forming desired films on the surfaces of the substrates. In recent years, in accordance with miniaturization and increasing performance of semiconductor devices, it is desirable to provide a substrate-processing method of forming a thin film having excellent in-plane uniformity in terms of film thickness.

For example, Japanese Patent Application Publication No. 2018-62703 discloses a substrate-processing apparatus in which gas supplies are disposed above, and correspondingly to, two horizontally aligned substrates in a process chamber. This substrate-processing apparatus is configured to rotate each of the gas supplies about a shaft between the two substrates and discharge gas to the individual substrates, thereby forming films.

### SUMMARY

One aspect of the present disclosure provides a substrate-processing method for processing a substrate. The substrate-processing method includes: (A) holding the substrate by a substrate holder in a process chamber and rotating the substrate; (B) discharging gas from a discharge hole of a nozzle gas discharge mechanism toward the substrate held by the substrate holder; and (C) moving the nozzle gas discharge mechanism relative to the substrate in a direction parallel to a surface of the substrate held by the substrate holder so that the discharge hole passes through a center of the substrate. In (C), a speed of a relative movement of the nozzle gas discharge mechanism is changed in accordance with a surface area of a section of the substrate, the section being faced by the discharge hole.

### BRIEF DESCRIPTION OF THE DRAWINGS

FIG. 1 is a schematic plan diagram illustrating a substrate-processing apparatus according to a first embodiment;

FIG. 2 is a schematic cross-sectional diagram cut along a diagonal line of a process chamber in the substrate-processing apparatus of FIG. 1;

FIG. 3A is a schematic cross-sectional diagram illustrating a tip end of a first nozzle gas discharge mechanism;

FIG. 3B is a schematic plan diagram illustrating a discharger of a first head;

FIG. 4A is a schematic cross-sectional diagram illustrating a tip end of a second nozzle gas discharge mechanism;

FIG. 4B is a schematic plan diagram illustrating a discharger of a second head;

FIG. 5 is a flowchart illustrating an example of a substrate-processing method;

FIG. 6A is a first explanatory diagram illustrating movements of the first nozzle gas discharge mechanism and a second nozzle gas discharge mechanism during substrate processing;

FIG. 6B is a second explanatory diagram illustrating movements of the first nozzle gas discharge mechanism and the second nozzle gas discharge mechanism during substrate processing;

FIG. 7A is a third explanatory diagram illustrating movements of the first nozzle gas discharge mechanism and the second nozzle gas discharge mechanism during substrate processing;

FIG. 7B is a fourth explanatory diagram illustrating movements of the first nozzle gas discharge mechanism and the second nozzle gas discharge mechanism during substrate processing;

FIG. 8A is a fifth explanatory diagram illustrating movements of the first nozzle gas discharge mechanism and the second nozzle gas discharge mechanism during substrate processing;

FIG. 8B is a sixth explanatory diagram illustrating movements of the first nozzle gas discharge mechanism and the second nozzle gas discharge mechanism during substrate processing;

FIG. 9 is a schematic plan diagram describing a swing speed of the first nozzle gas discharge mechanism;

FIG. 10A is a table illustrating an example of a swing speed in individual sections when a rotation speed of a susceptor is 240 rpm;

FIG. 10B is a table illustrating an example of the swing speed in the individual sections when the rotation speed of the susceptor is 120 rpm;

FIG. 10C is a table illustrating an example of the swing speed in the individual sections when the rotation speed of the susceptor is 60 rpm;

FIG. 10D is a table illustrating an example of the swing speed in the individual sections when the rotation speed of the susceptor is 30 rpm;

FIG. 11A is a schematic side cross-sectional diagram illustrating an example of a pattern of a substrate;

FIG. 11B is a schematic side cross-sectional diagram illustrating another example of the pattern of the substrate;

FIG. 12A is a diagram illustrating a first example of a shape of a film formed on the substrate;

FIG. 12B is a diagram illustrating a second example of the shape of the film formed on the substrate;

FIG. 12C is a diagram illustrating a third example of the shape of the film formed on the substrate;

FIG. 13 is a block diagram illustrating functional components that are constructed in a controller for control of the swing speed; and

FIG. 14 is a plan diagram illustrating a substrate-processing apparatus according to a modified example.

### DETAILED DESCRIPTION OF THE INVENTION

The present disclosure provides a technique capable of performing substrate processing on the surface of a substrate with high accuracy.

Hereinafter, embodiments of the present disclosure will be described with reference to the drawings. In the drawings, the same components may be denoted by the same reference symbols, and duplicate description thereof may be omitted.

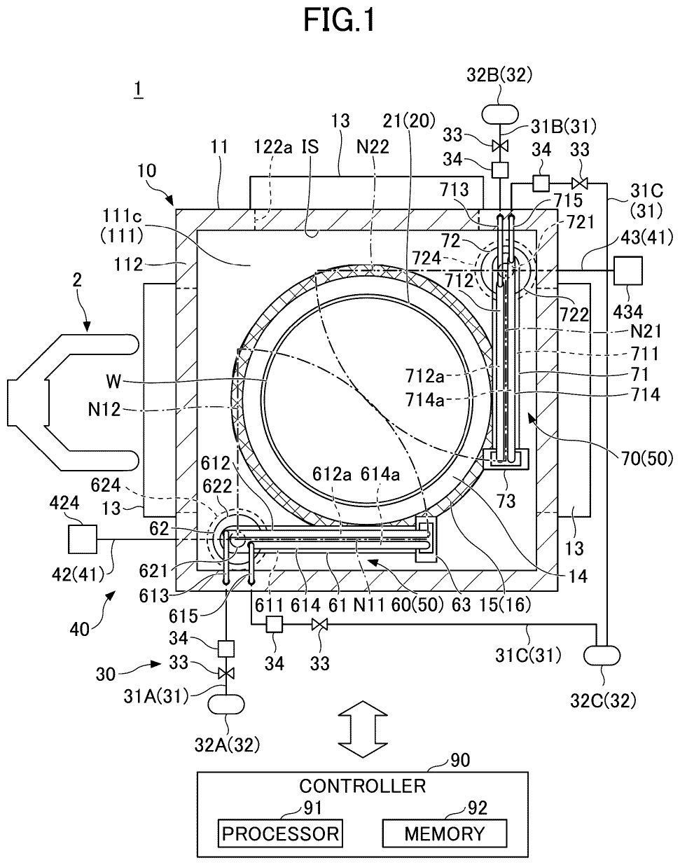

As illustrated in FIG. 1, a substrate-processing apparatus 1 according to the embodiment is configured as a single-wafer type substrate-processing apparatus 1 configured to process substrates W one by one. The substrate-processing apparatus 1 performs film formation through atomic layer deposition (ALD) or molecular layer deposition (MLD) as the substrate processing.

Examples of the substrate W to be subjected to film formation include semiconductor wafers of a silicon semiconductor, a compound semiconductor, an oxide semiconductor, and the like. The substrate W may have a pattern, such as a trench, a via, or the like. The substrate-processing apparatus 1 of the present disclosure is not limited to the configuration that performs the film formation as the substrate processing. The substrate-processing apparatus 1 of the present disclosure may be an apparatus configured to perform an etching process of etching a film on the substrate W, a cleaning process of removing a deposit on the substrate W, or the like.

The substrate-processing apparatus 1 includes a process chamber 10, a substrate holder 20, a gas supply 30, a gas exhauster 40, and a nozzle gas discharge mechanism 50. The substrate-processing apparatus 1 also includes a controller 90 configured to control movements of individual components of the substrate-processing apparatus 1.

The process chamber 10 is a rectangular box-shaped chamber having an inner space IS capable of housing the substrate W. The size of the process chamber 10 is preferably set in accordance with the size of the substrate W to be processed. For example, when the diameter of the substrate W is 300 mm, the process chamber 10 is formed with each side having a length of from about 400 mm through about 500 mm.

A gate valve 13 configured to open and close the inner space IS is provided on lateral sides of the process chamber 10. The substrate-processing apparatus 1 opens the gate valve 13 before the film formation, and carries the substrate W into the inner space IS from the exterior of the process chamber 10 by a carrier 2 provided in an unillustrated substrate-processing system. After the substrate W is carried, the substrate-processing apparatus 1 closes the gate valve 13 and performs the film formation. After completion of the film formation, the substrate-processing apparatus 1 opens the gate valve 13, and causes the carrier 2 to enter the inner space IS again and carries the substrate W to the exterior of the process chamber 10. The substrate-processing apparatus 1 as illustrated in FIG. 1 includes multiple (three) gate valves 13 and can carry the substrate W into and out of the process chamber 10 from a desired one of the gate valves 13. However, it is enough that the process chamber 10 is provided with at least one gate valve 13.

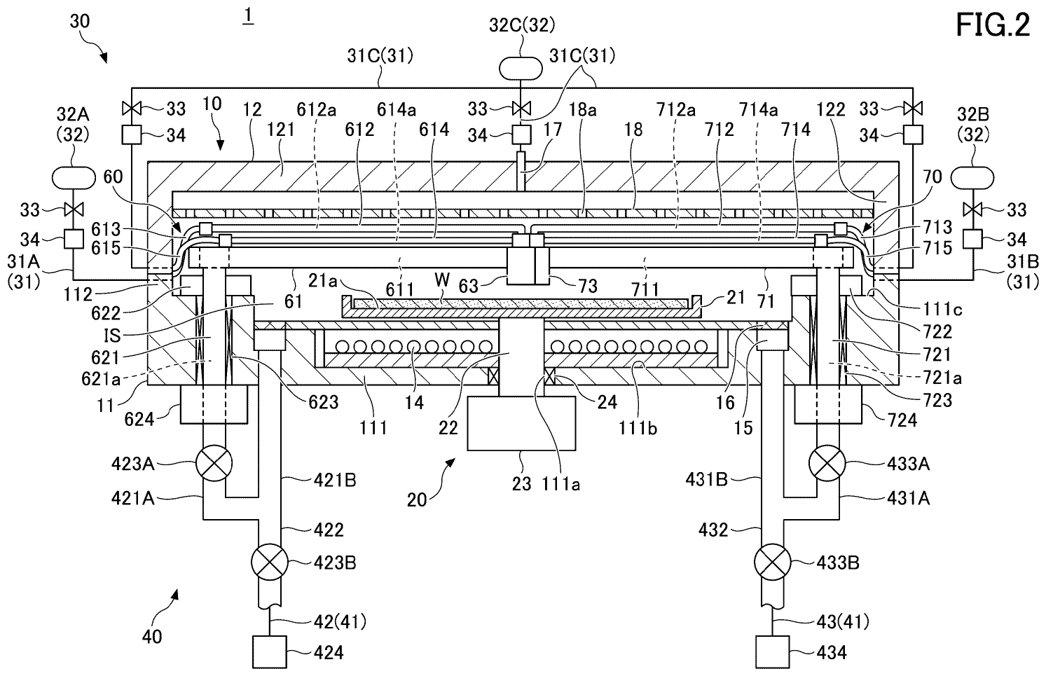

As illustrated in FIG. 2, the process chamber 10 includes: a lower recessed chamber 11 that is open on the upper side; and an upper recessed chamber 12 that is open on the lower side. The lower recessed chamber 11 is covered by the upper recessed chamber 12. The lower recessed chamber 11 and the upper recessed chamber 12 are fixed so as to close the openings of each other, thereby forming the inner space IS of the process chamber 10. For the sake of convenience, FIG. 1 illustrates the substrate-processing apparatus 1 with the upper recessed chamber 12 being removed.

The lower recessed chamber 11 includes: a bottom wall 111 that is formed in an approximately square shape in a plan view; and an outer edge projection 112 that is slightly projecting from the four outer edges of the bottom wall 111 upward in the vertical direction. The lower recessed chamber 11 includes the substrate holder 20 therein. A through hole 111a through which the below-described shaft 22 of the substrate holder 20 passes is formed at a center of the bottom wall 111. A center region including the center of the bottom wall 111 is a depressed portion 111b that is depressed downward with respect to an annular region next to the depressed portion 111b. Also, a peripheral base 111c projecting upward of the annular region is formed outward of the annular region of the bottom wall 111 and between the annular region of the bottom wall 111 and the outer edge projection 112.

A temperature controller 14 configured to control the temperature of the substrate W held by the substrate holder 20 is disposed in the depressed portion 111b. No particular limitation is imposed on the temperature controller 14, which may have a configuration including a heater, such as an electric heat wire or the like, or may have a configuration that circulates a temperature-controlled medium, which is temperature-controlled by a heat exchanger or the like, along an appropriate flow path. The temperature controller 14 is connected to the controller 90 via an unillustrated temperature control driver or the like, and the temperature of the substrate W is controlled under the control of the controller 90.

Meanwhile, the upper recessed chamber 12 includes: a ceiling wall 121 that is formed in an approximately square shape (the same shape as the shape of the bottom wall 111) in a plan view; and a side wall 122 that is slightly projecting from the four outer edges of the ceiling wall 121 downward in the vertical direction. The process chamber 10 is fixed such that the lower end of the side wall 122 and the upper end of the outer edge projection 112 face each other. By providing an unillustrated seal member between the lower end of the side wall 122 and the upper end of the outer edge projection 112, the inner space IS is airtightly closed. The gate valve 13 opens and closes, for example, a side opening 122a formed in the side wall 122 (see FIG. 1).

The substrate holder 20 provided in the process chamber 10 rotatably holds the substrate W. The substrate holder 20 includes: a susceptor 21 configured to directly hold the substrate W; a shaft 22 configured to support the susceptor 21; and a substrate rotator 23 connected to the shaft 22 externally of the process chamber 10.

The susceptor 21 is formed in a regular circular shape that is slightly larger than the substrate W in a plan view. The susceptor 21 includes a stage 21a that extends horizontally in the process chamber 10. An edge is formed around the stage 21a, the edge projecting by the same length as the thickness of the substrate W or by a length greater than the thickness of the substrate W. The substrate holder 20 also includes unillustrated multiple lift pin raising and lowering mechanisms configured to receive and deliver the substrate W between the substrate holder 20 and the carrier 2. The susceptor 21 may be configured to fix the substrate W by an appropriate holding method (mechanical locking, suctioning, electrostatic chuck, or the like) upon placement of the substrate W on the stage 21a.

The shaft 22 is connected to the lower surface and the center of the susceptor 21, and extends along the axial direction (vertical direction) of the process chamber 10. The substrate rotator 23 rotates the shaft 22 about the axis thereof, thereby rotating the susceptor 21. A magnetic fluid sealing 24 configured to rotatably seal the shaft 22 is provided between the outer peripheral surface of the shaft 22 and the through hole 111a of the bottom wall 111 of the process chamber 10.

The substrate rotator 23 includes an unillustrated motor and an unillustrated driving force transmitter that connects the motor and the shaft 22. The motor of the substrate rotator 23 is connected to the controller 90 via an unillustrated driver. When the motor of the substrate rotator 23 receives a power that is adjusted by the driver based on a command of the controller 90, the substrate rotator 23 rotates the shaft 22 at an appropriate rotational speed.

As illustrated in FIG. 1 and FIG. 2, the gas supply 30 includes multiple supply paths 31 that cause gases to flow externally of the process chamber 10, the gases including process gases (adsorbing gas, reactive gas), purge gas, and the like. Through the respective supply paths 31, gases are supplied into the process chamber 10.

The process gases to be supplied to the process chamber 10 are appropriately selected in accordance with a type of a film to be formed on the substrate W. For example, when a silicon oxide film (SiO₂ film) is formed, a silicon-containing gas, such as a silane-based gas or the like, can be used as the adsorbing gas. Also, an oxygen-containing gas, such as oxygen (O₂) gas, ozone (O₃) gas, or the like, can be used as the reactive gas. Further, an inert gas, such as nitrogen (Ne) gas, argon (Ar) gas, or the like, can be used as the purge gas.

The supply paths 31 include, for example, an adsorbing gas supply path 31A through which the adsorbing gas flows, a reactive gas supply path 31B through which the reactive gas flows, and a purge gas supply path 31C through which the purge gas flows. The purge gas supply path 31C includes multiple flow paths for supplying the purge gas to both the nozzle gas discharge mechanism 50 and the process chamber 10.

The supply paths 31 include: multiple tanks 32 configured to store gases; multiple opening/closing valves 33 configured to open/close the supply paths 31; and multiple flow rate regulators 34 configured to regulate the flow rates of the gases that are flowing through the flow paths of the supply paths 31. The tanks 32 include, for example, an adsorbing gas tank 32A configured to store the adsorbing gas, a reactive gas tank 32B configured to store the reactive gas, and a purge gas tank 32C configured to store the purge gas. Also, each of the opening/closing valves 33 and each of the flow rate regulators 34 are connected to the controller 90 via an appropriate driver. The controller 90 opens the opening/closing valves 33 of the supply paths 31 for predetermined gases at appropriate timings during the substrate processing, and regulates the flow rates of the gases by the flow rate regulators 34, thereby supplying the predetermined gases to the process chamber 10.

Meanwhile, the gas exhauster 40 includes multiple exhaust paths 41 that cause gases to flow externally of the process chamber 10, the gases including reacted gas, unreacted gas, purge gas, and the like. Through the respective exhaust paths 41, the gases supplied into the process chamber 10 are exhausted. The exhaust paths 41 are divided into two lines in accordance with the below-described two discharge mechanisms of the nozzle gas discharge mechanism 50, i.e., a first nozzle gas discharge mechanism 60 and a second nozzle gas discharge mechanism 70.

A first exhaust path 42 is connected to the first nozzle gas discharge mechanism 60 and a position in the vicinity thereof. The first exhaust path 42 mainly exhausts the gas discharged from the first nozzle gas discharge mechanism 60. The first exhaust path 42 includes: two or more (2) branched exhaust paths 421; and a merged exhaust path 422 in which the branched exhaust paths 421 are merged and through which the gases are collectively exhausted. One of the branched exhaust paths 421A is directly connected to the first nozzle gas discharge mechanism 60, and exhausts the gas of the first nozzle gas discharge mechanism 60. The branched exhaust path 421A is provided with a pressure adjusting valve 423A configured to adjust the pressure of the gas suctioned in the first nozzle gas discharge mechanism 60.

The other branched exhaust path 421B is connected to the annular region of the bottom wall 111 of the process chamber 10, and exhausts the gas of the inner space IS around the susceptor 21. The bottom wall 111 is provided with an exhaust groove 15 that annularly runs laterally of the temperature controller 14 (see FIG. 1). The branched exhaust path 421B is in communication with the bottom of the exhaust groove 15. In order to uniform a conductance upon exhaustion of the gas in the circumferential direction, an exhaust net 16 is preferably provided at the upper opening of the exhaust groove 15.

In order to suction the gas of the entire first exhaust path 42, a suction mechanism 424 (e.g., a turbomolecular pump, a vacuum pump, or the like) is connected to one end of the merged exhaust path 422. Further, the merged exhaust path 422 is provided with a pressure adjusting valve 423B configured to adjust the pressure of the gas suctioned in the entire first line.

A second exhaust path 43 is connected to the second nozzle gas discharge mechanism 70 and a position in the vicinity thereof. The second exhaust path 43 mainly exhausts the gas discharged from the second nozzle gas discharge mechanism 70. Similar to the first exhaust path 42, the second exhaust path 43 includes: two or more (2) branched exhaust paths 431; and a merged exhaust path 432 in which the branched exhaust paths 431 are merged and through which the gases are collectively exhausted. One of the branched exhaust paths 431A is directly connected to the second nozzle gas discharge mechanism 70, and exhausts the gas of the second nozzle gas discharge mechanism 70. The branched exhaust path 431A is provided in the middle with a pressure adjusting valve 433A configured to adjust the pressure of the gas suctioned in the second nozzle gas discharge mechanism 70. The other branched exhaust path 431B is connected to the annular region (the bottom of the exhaust groove 15) of the bottom wall 111 of the process chamber 10, and exhausts the gas of the inner space IS around the susceptor 21.

In order to suction the gas of the entire second exhaust path 43, a suction mechanism 434 (e.g., a turbomolecular pump, a vacuum pump, or the like) is connected to one end of the merged exhaust path 432. Further, the merged exhaust path 432 is provided in the middle with a pressure adjusting valve 433B configured to adjust the pressure of the gas suctioned in the entire second line.

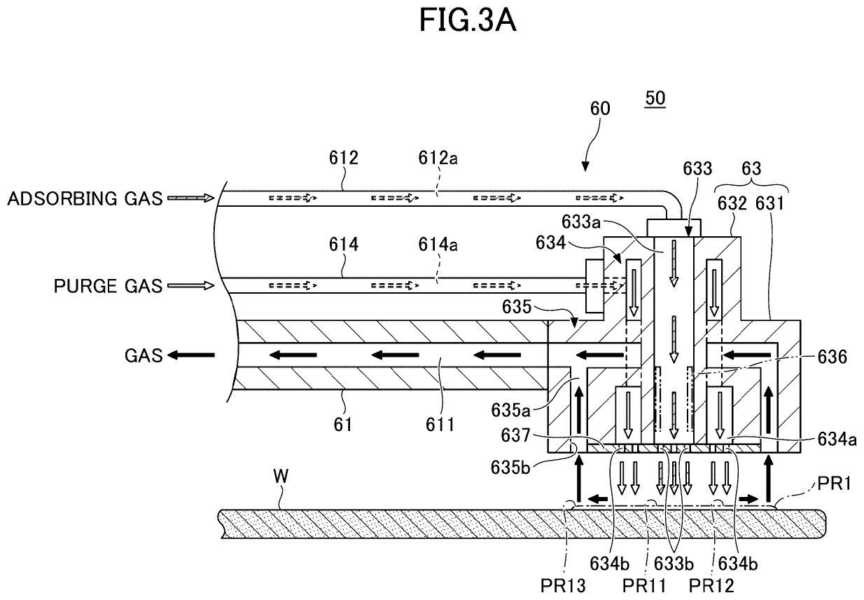

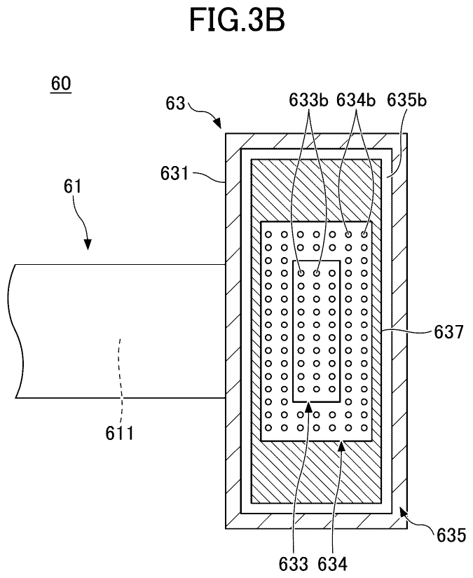

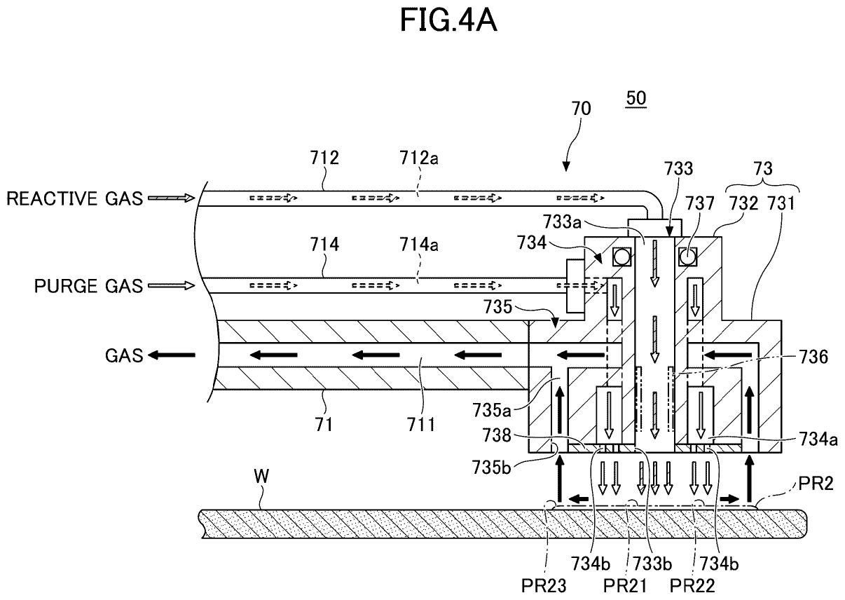

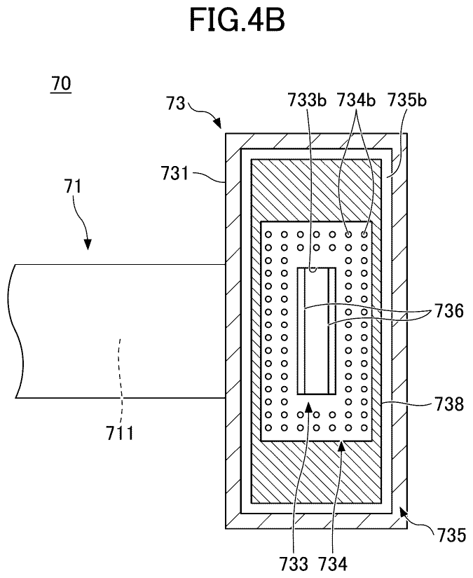

The nozzle gas discharge mechanism 50 has a function of discharging the process gas and the purge gas to the upper surface (front surface) of the substrate W held by the susceptor 21 in the process chamber 10. In addition, the nozzle gas discharge mechanism 50 has a function of suctioning the gas above the substrate W. The nozzle gas discharge mechanism 50 includes the first nozzle gas discharge mechanism 60 and the second nozzle gas discharge mechanism 70 in accordance with the type of the process gas supplied to the substrate W (adsorbing gas, reactive gas). The substrate-processing apparatus 1 swings each of the first nozzle gas discharge mechanism 60 and the second nozzle gas discharge mechanism 70 relative to the substrate holder 20 in the process chamber 10. Thereby, a first processing point region PR1 (see FIG. 3A) where gases are discharged and suctioned in the first nozzle gas discharge mechanism 60 moves independently of a second processing point region (see FIG. 4A) where gases are discharged and suctioned in the second nozzle gas discharge mechanism 70.

The first nozzle gas discharge mechanism 60 is disposed at one corner (the left-lower corner in FIG. 1) of the four corners of the process chamber 10 (the lower recessed chamber 11). The first nozzle gas discharge mechanism 60 discharges the adsorbing gas and the purge gas and suctions the discharged gases. Specifically, the first nozzle gas discharge mechanism 60 includes: a first nozzle 61; a first nozzle driver 62 provided at the base end of the first nozzle 61; and a first head 63 provided at the projecting end (tip end) of the first nozzle 61.

The first nozzle 61 is disposed at the peripheral base 111c of the bottom wall 111, and extends in parallel (horizontally) to the stage 21a of the susceptor 21 at a position that is higher than the substrate W placed on the susceptor 21. The first nozzle 61 is formed in a length that can extend from the first nozzle driver 62 in the process chamber 10 to the center of the process chamber 10. The center of the process chamber 10 coincides with the center of the susceptor 21 (substrate W) and the first nozzle 61 extends to the center of the susceptor 21. That is, the extended length of the first nozzle 61 is set to be slightly shorter than half the diagonal line of the process chamber 10, and is set to be longer than the radius of the susceptor 21.

The first nozzle 61 is formed, for example, in a rectangular cylinder in a cross-sectional view, and has a flow path 611 therein through which the gas can flow. Also, multiple tubes 612 and 614 are provided at appropriate positions (e.g., the top surface) on the outer peripheral surface of the first nozzle 61 in the process chamber 10. The tubes 612 and 614 extend from the base of the first nozzle 61 to the first head 63 of the first nozzle 61 in parallel to the extending direction of the first nozzle 61.

The tube 612 has a flow path 612a therein extending along the axial direction thereof. The base end of the tube 612 is connected to a connection tube 613 provided in the process chamber 10. The connection tube 613 has appropriate flexibility so that the tube 612 can move in conformity to the rotation of the first nozzle 61. The connection tube 613 is connected to the adsorbing gas supply path 31A externally of the process chamber 10 via a connector provided in the process chamber 10. Thus, the tube 612 can deliver the adsorbing gas from the base end to the first head 63 along the flow path 612a.

The tube 614 has a flow path 614a extending along the axial direction thereof. The base end of the tube 614 is connected to a connection tube 615 provided in the process chamber 10. The connection tube 615 has appropriate flexibility so that the tube 614 can move in conformity to the rotation of the first nozzle 61. The connection tube 615 is connected to the purge gas supply path 31C externally of the process chamber 10 via a connector provided in the process chamber 10. Thus, the tube 614 can deliver the purge gas from the base end to the first head 63 along the flow path 614a.

The flow path 611 of the first nozzle 61 has a cross-sectional flow path area that is larger than that of the flow path 612a of the tube 612 and that of the flow path 614a of the tube 614. The flow path 611 delivers the gas suctioned at the outer periphery of the first head 63, and exhausts the gas to the branched exhaust path 421A via a support shaft 621. The base end of the first nozzle 61 is connected to the support shaft 621 of the first nozzle driver 62. In accordance with the movement of the support shaft 621, the first nozzle 61 and the first head 63 are caused to swing (to repeatedly move) in the form of an arc, with the support shaft 621 being a swing axis.

The first nozzle driver 62 rotates the support shaft 621 while ensuring the flow of the gas through the flow path 611 of the first nozzle 61. To do this, the first nozzle driver 62 includes a cover 622, a magnetic fluid sealing 623, and a drive body 624, in addition to the support shaft 621.

The support shaft 621 extends in the vertical direction and is formed into a circular hard tube having a flow path 621a therein. The upper end of the support shaft 621 firmly fixes the first nozzle 61, extending in the horizontal direction, using an appropriate fixing member. The lower end of the support shaft 621 is connected to the branched exhaust path 421A externally of the process chamber 10 via an unillustrated connector provided in the process chamber 10. Thereby, the first nozzle 61 can suction the gases from the branched exhaust path 421A, the flow path 621a, and the flow path 611 in this order by applying a suction force (negative pressure) to the first head 63 provided at the tip end of the first nozzle 61.

The magnetic fluid sealing 623 airtightly seals the space between the bottom wall 111 and the support shaft 621, thereby preventing leakage of the gas from the interior of the process chamber 10 through the first nozzle driver 62. The drive body 624 includes an unillustrated rotary motor and an unillustrated driving force transmitter, and is configured to rotate the support shaft 621 over a set angle range in response to rotary driving of the rotary motor. As the support shaft 621 rotates, the first nozzle 61 swings, with the base end connected to the support shaft 621 being a swing axis. The drive body 624 is connected to the controller 90 via an unillustrated driving driver, and the rotation speed, rotation direction, and the like of the rotary motor are controlled under the control of the controller 90.

The first nozzle driver 62 is controlled to repeat clockwise rotation as illustrated in FIG. 1 and counterclockwise rotation as illustrated in FIG. 1 over a range of approximately 90° (degrees). By the movement of the first nozzle driver 62, the first nozzle 61 swings between: one first nozzle movement end N11 set near one side of the process chamber 10; and the other first nozzle movement end N12 set near the other side continuous and orthogonal to the one side of the process chamber 10. The one first nozzle movement end N11 and the other first nozzle movement end N12 are at positions having an appropriate gap from the susceptor 21 in the horizontal direction (i.e., at positions not overlapping the susceptor 21 in the vertical direction).

As illustrated in FIG. 3A and FIG. 3B, the first head 63 provided at the tip end of the first nozzle 61 is formed, in a plan view, in a rectangular shape that is longer in a direction orthogonal to the extending direction of the first nozzle 61. The first head 63 forms the first processing point region PR1, where during the substrate processing, the adsorbing gas is discharged to the substrate W, the purge gas is discharged to the substrate W around the adsorbing gas, and the gas is suctioned externally of the dischargers for the adsorbing gas and the purge gas. The first head 63 is caused to repeatedly move along a first arc path in accordance with swing of the first nozzle 61 between the one first nozzle movement end N11 and the other first nozzle movement end N12. During this movement, the first head 63 faces the substrate W (see FIG. 1).

Specifically, the first head 63 includes: a rectangular head body 631 that is longer in the tangential direction of the first arc path; and a projection 632 projecting from the upper surface of the head body 631. The first nozzle 61 is directly connected to the head body 631, and the tube 612 and the tube 614 as described above are connected to the projection 632. The first head 63 includes a process gas discharger 633, configured to discharge the adsorbing gas, at the center of the head body 631 and at the center of the projection 632.

The process gas discharger 633 is enclosed by: an inner wall extending over the head body 631 and the projection 632; and a bottom wall (discharge plate 637) facing the substrate W of the head body 631. The process gas discharger 633 has a discharge path 633a therein, and has multiple discharge holes 633b that are in communication with the discharge path 633a at the bottom wall. The tube 612 is connected to the projection 632 so that the discharge path 633a and the flow path 612a communicate with each other. The process gas discharger 633 may include, in the discharge path 633a, a heater 636 configured to heat the adsorbing gas supplied from the flow path 612a.

The discharge holes 633b of the process gas discharger 633 are arranged in a matrix and, as a whole, form a rectangular shape that is longer in the tangential direction of the first arc path. Thereby, the process gas discharger 633 forms a rectangular adsorbing gas discharge region PR11 at the center of the first processing point region PR1. That is, during the substrate processing, the process gas discharger 633 can apply the adsorbing gas to a sufficiently small range of the area of the entire substrate W.

Further, the first head 63 includes a purge gas discharger 634, configured to discharge the purge gas, around the process gas discharger 633. The purge gas discharger 634 is enclosed: between an inner wall and an outer wall of the projection 632; between an inner wall and a partition wall of the head body 631; and by the bottom wall. The purge gas discharger 634 has a discharge path 634a therein, and has multiple discharge holes 634b that are in communication with the discharge path 634a at the bottom wall. The tube 614 is connected to the projection 632 so that the discharge path 634a and the flow path 614a communicate with each other.

Similar to the discharge holes 633b, the discharge holes 634b of the purge gas discharger 634 are arranged in a matrix, and form a rectangularly annular shape around the discharge holes 633b of the process gas discharger 633. Thereby, the purge gas discharger 634 forms a rectangularly annular purge gas discharge region PR12 externally of the adsorbing gas discharge region. The purge gas discharger 634 prevents the discharge of the purge gas from spreading outward the adsorbing gas discharged by the process gas discharger 633 during the substrate processing.

The first head 63 includes a gas suction section 635, configured to suction the gas, around the purge gas discharger 634. The gas suction section 635 is enclosed by the partition wall and an outer wall of the head body 631. The gas suction section 635 has a suction path 635a therein, and has a continuous opening 635b that is in communication with the suction path 635a. The first nozzle 61 and the head body 631 are connected so that the suction path 635a and the flow path 611 communicate with each other.

The opening 635b is formed in a rectangularly annular shape around the outer periphery of the bottom wall of the head body 631. Thereby, the gas suction section 635 forms a rectangularly annular suction region PR13 externally of the purge gas discharge region. The gas suction section 635 can smoothly suction the adsorbing gas and the purge gas, discharged onto the substrate W, around the discharge region PR12 during the substrate processing.

As illustrated in FIG. 1 and FIG. 2, the second nozzle gas discharge mechanism 70 is disposed at another corner (the right-upper corner in FIG. 1) located at a position diagonal to the first nozzle gas discharge mechanism 60 of the four corners of the process chamber 10. The second nozzle gas discharge mechanism 70 discharges the reactive gas and the purge gas and suctions the discharged gases. Specifically, the second nozzle gas discharge mechanism 70 includes: a second nozzle 71; a second nozzle driver 72 provided at the base end of the second nozzle 71; and a second head 73 provided at the projecting end (tip end) of the second nozzle 71.

The second nozzle 71 is basically formed in the same shape as that of the first nozzle 61. That is, a flow path 711 is provided in the second nozzle 71. Also, multiple tubes 712 and 714 are provided at appropriate positions (e.g., the top surface) on the outer peripheral surface of the second nozzle 71. The tube 712 has a flow path 712a therein, and the base end thereof is connected to a connection tube 713 provided in the process chamber 10. The connection tube 713 is connected to the reactive gas supply path 31B provided externally of the process chamber 10. The tube 714 has a flow path 714a therein, and the base end thereof is connected to a connection tube 715 provided in the process chamber 10. The connection tube 715 is connected to a purge gas supply path 31C provided externally of the process chamber 10.

The second nozzle driver 72 is also formed in the same manner as in the first nozzle driver 62. That is, the second nozzle driver 72 includes: a support shaft 721, a cover 722, a magnetic fluid sealing 723, and a drive body 724. The support shaft 721 is formed into a circular hard tube having a flow path 721a therein. The upper end of the support shaft 721 supports the second nozzle 71, and the lower end of the support shaft 721 is connected to a branched exhaust path 431A provided externally of the process chamber 10. Also, the drive body 724 includes an unillustrated rotary motor and an unillustrated driving force transmitter, and is configured to rotate the support shaft 721 over a set angle range in response to rotary driving of the rotary motor. The drive body 724 is connected to the controller 90 via an unillustrated driving driver, and the rotation speed, rotation direction, and the like of the rotary motor are controlled under the control of the controller 90.

The second nozzle driver 72 is controlled to repeat clockwise rotation and counterclockwise rotation about the support shaft 721 over a range of approximately 90°. By the movement of the second nozzle driver 72, the second nozzle 71 swings between: one second nozzle movement end N21 set near one side of the process chamber 10; and the other second nozzle movement end N22 set near the other side orthogonal to the one side of the process chamber 10. The one second nozzle movement end N21 and the other second nozzle movement end N22 are at positions having an appropriate gap from the susceptor 21 in the horizontal direction (i.e., at positions not overlapping the susceptor 21 in the vertical direction).

As illustrated in FIG. 4A and FIG. 4B, the second head 73 is basically formed in the same manner as in the first head 63. The second head 73 forms a second processing point region PR2, where during the substrate processing, the reactive gas is discharged to the substrate W, the purge gas is discharged to the substrate W around the reactive gas, and the gas is suctioned externally of the dischargers for the reactive gas and the purge gas. The second head 73 is caused to repeatedly move along a second arc path in accordance with swing of the second nozzle 71 between the one second nozzle movement end N21 and the other second nozzle movement end N22. During this movement, the second head 73 faces the substrate W.

Specifically, the second head 73 includes: a rectangular head body 731 that is longer in the tangential direction of the second arc path; and a projection 732 projecting from the upper surface of the head body 731. The tube 712 and the tube 714 are connected to the projection 732. The second head 73 includes a process gas discharger 733, configured to discharge the reactive gas, at the center of the head body 731 and at the center of the projection 732.

The process gas discharger 733 is enclosed by: an inner wall extending over the head body 731 and the projection 732; and a bottom wall (discharge plate 738) facing the substrate W of the head body 731. The process gas discharger 733 has a discharge path 733a therein, and has a discharge hole 733b that is in communication with the discharge path 733a. The tube 712 is connected to the projection 732 so that the discharge path 733a and the flow path 712a communicate with each other. In this embodiment, the discharge hole 733b has a rectangular shape that is continuous in the longitudinal direction thereof. However, this is by no means a limitation. The second head 73 may have multiple discharge holes similar to the first head 63. The process gas discharger 733 may include, in the discharge path 733a, a heater 736 configured to heat the reactive gas supplied from the flow path 712a.

In addition, the process gas discharger 733 may discharge the reactive gas as is (or after heating) in accordance with requests for the substrate processing. The process gas discharger 733 may be configured to discharge the reactive gas after being formed into a plasma. In the following, a specific description will be given of a configuration in which the process gas discharger 733 discharges the reactive gas after being formed into a plasma. The process gas discharger 733 includes a plasma antenna 737 around the outer peripheral surface of the inner wall of the projection 732. The antenna 737 is connected to an unillustrated high-frequency power supply provided externally of the process chamber 10 via an unillustrated interconnect. For example, the interconnect extends along the outer peripheral surface of the second nozzle 71. Therefore, during the substrate processing, a high-frequency power is supplied from the high-frequency power supply to the antenna 737 via the interconnect, thereby generating a plasma in the reactive gas flowing through the discharge path 733a.

When the reactive gas is formed into a plasma, the reactive gas for use may be, for example, a gas mixture obtained by appropriately mixing O₂, H₂, NH₃, Ar, N₂, and the like. In addition, in order to form a high-quality oxide film, an O₃—containing purge gas may be supplied as the purge gas in the generation of the plasma. Thereby, upon discharge of the reactive gas, the process gas discharger 733 can form a reactive (plasma) gas discharge region PR21 at the center of the second processing point region PR2.

Further, the second head 73 includes a purge gas discharger 734, configured to discharge the purge gas, around the process gas discharger 733. The purge gas discharger 734 can have the same configuration as that of the purge gas discharger 634 of the first head 63. That is, the purge gas discharger 734 has a discharge path 734a and multiple discharge holes 734b, and forms a purge gas discharge region PR22. The second head 73 has a gas suction section 735, configured to suction the gas, around the purge gas discharger 734. The gas suction section 735 can have the same configuration as that of the gas suction section 635 of the first head 63. That is, the gas suction section 735 has a suction path 735a and an opening 735b, and forms a gas suction region PR23.

As illustrated in FIG. 2, the substrate-processing apparatus 1 further includes a mechanism configured to supply the purge gas from the upper part (above the nozzle gas discharge mechanism 50) of the process chamber 10 to the lower inner space IS. For example, the ceiling wall 121 of the upper recessed chamber 12 includes a gas introducing port 17 configured to introduce the purge gas. The gas introducing port 17 is connected to a purge gas tank 32C, storing the purge gas, through the purge gas supply path 31C including the opening/closing valve 33 and the flow rate regulator 34.

A shower head 18 may be provided in the upper recessed chamber 12 in order to horizontally diffuse the purge gas introduced from the gas introducing port 17. The shower head 18 is formed in the form of a flat plate having multiple gas holes 18a. The shower head 18 uniformly discharges the purge gas, supplied to the space between the shower head 18 and the ceiling wall 121, to a space below the shower head 18 (a space including the substrate W and the nozzle gas discharge mechanism 50).

As illustrated in FIG. 1, a computer including a processor 91, a memory 92, an unillustrated input/output interface, and the like can be applied as the controller 90 configured to control the substrate-processing apparatus 1. The processor 91 is a combination of one or more of a central processing unit (CPU), a graphics processing unit (GPU), an application specific integrated circuit (ASIC), a field-programmable gate array (FPGA), a circuit formed of multiple discrete semiconductors, and the like. The memory 92 is an appropriate combination of a volatile memory and a nonvolatile memory (e.g., a compact disc, a digital versatile disc (DVD), a hard disk, a flash memory, or the like).

The memory 92 stores: programs for driving the substrate-processing apparatus 1; and recipes, such as process conditions for the substrate processing, and the like. The processor 91 reads and executes the program of the memory 92, and controls the components of the substrate-processing apparatus 1. The controller 90 may be configured by a host computer or multiple client computers that perform information communication via a network.

The substrate-processing apparatus 1 according to the first embodiment is basically configured as described above. The substrate-processing method performed by the substrate-processing apparatus 1 will be described below.

The controller 90 controls the components of the substrate-processing apparatus 1, and performs film formation (substrate processing) on the substrate W held by the substrate holder 20. At this time, the controller 90 moves (swings) the first nozzle 61 and the second nozzle 71 independently of each other in a state in which the substrate W is being rotated by the substrate holder 20.

Specifically, after the substrate W is placed on the susceptor 21 of the substrate holder 20, the controller 90 closes the gate valve 13 and starts the substrate processing. As illustrated in FIG. 5, the controller 90 first operates the gas supply 30 and the gas exhauster 40, and adjusts the internal pressure of the process chamber 10 so as to reach the set target pressure by supplying the purge gas from the upper part of the process chamber 10 and exhausting the gas in the process chamber 10 (step S1). The internal pressure of the process chamber 10 can be appropriately set in accordance with, for example, the type of the substrate processing. For example, the internal pressure of the process chamber 10 can be set in the range of from 1 Torr through 10 Torr. By continuous supply of the purge gas from the entire upper part, the process chamber 10 can prevent the movement of the process gas to the space above the nozzle gas discharge mechanism 50 upon subsequent discharge of the process gas.

Also, the controller 90 operates the temperature controller 14 in the process chamber 10, thereby adjusting the temperature of the substrate W placed on the susceptor 21 (step S2). The temperature of the substrate W can be appropriately set in accordance with, for example, the type of the substrate processing. For example, the temperature of the substrate W can be set in the range of from about 100° C. (degrees Celsius) through 800° C.

Further, the controller 90 operates the substrate rotator 23 of the substrate holder 20, thereby rotating the susceptor 21 at an appropriate speed (step S3: (A)). For example, the controller 90 rotates the susceptor 21 at a rotation speed in the range of from 10 rpm through 1,000 rpm. Thereby, the substrate W held by the susceptor 21 also rotates (pivots) with the center thereof being a rotation axis.

Further, the controller 90 starts the operation of the first nozzle gas discharge mechanism 60 and the second nozzle gas discharge mechanism 70 in a state in which the rotation speed of the substrate W, the temperature of the substrate W, and the like become stable (step S4: (C)). That is, the controller 90 controls the operation of the first nozzle driver 62 and swings the first nozzle 61 in parallel to the surface of the substrate W, and controls the operation of the second nozzle driver 72 and swings the second nozzle 71 in parallel to the surface of the substrate W.

As described above, the first head 63 repeatedly moves along the first arc path in accordance with the swing of the first nozzle 61. The second head 73 repeatedly moves along the second arc path in accordance with the swing of the second nozzle 71. The first arc path and the second arc path cross each other at the center of the susceptor 21 (of the substrate W). For example, the controller 90 controls the swing speed of the first nozzle 61 and the swing speed of the second nozzle 71 so as to be the same, and controls the start timing of the swing of the first nozzle 61 and the start timing of the swing of the second nozzle 71 so as to be different. Thereby, it is possible to avoid interference between the first head 63 and the second head 73.

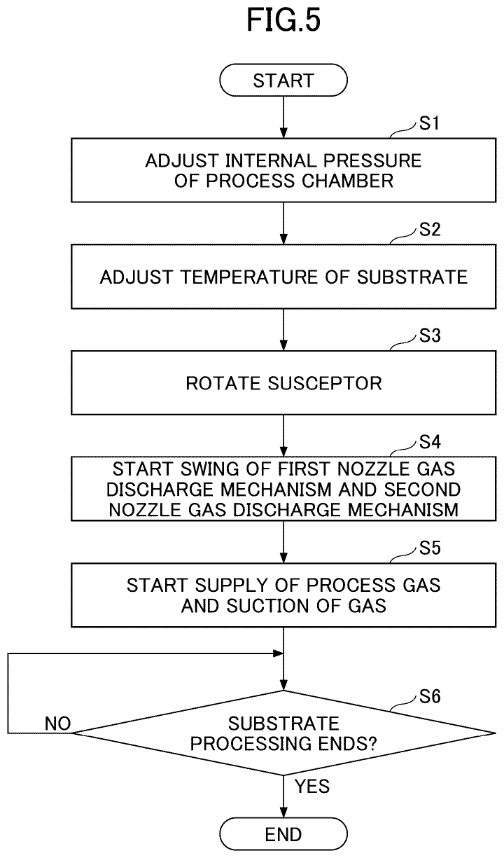

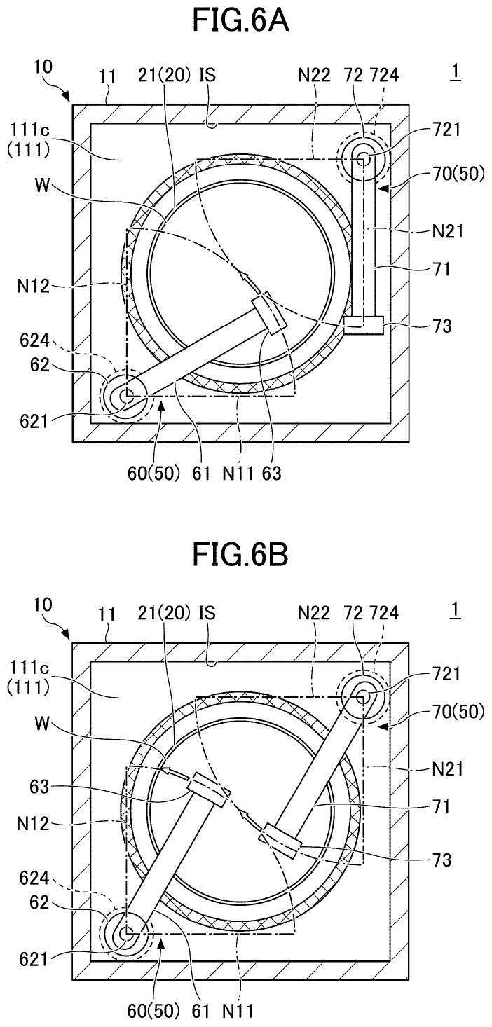

As an example, as illustrated in FIG. 6A, the controller 90 starts an outgoing movement of the first nozzle 61 from the one first nozzle movement end N11, and starts an outgoing movement of the second nozzle 71 from the one second nozzle movement end N21 at the timing when a start delay period has elapsed from the start timing of the outgoing movement of the first nozzle 61. Thereby, as illustrated in FIG. 6B, the discharge holes 633b of the first head 63 reach a position above the center of the substrate W and pass over the center of the substrate W. Subsequently, the discharge hole 733b of the second head 73 reach a position above the center of the substrate W and passes through the center of the substrate W.

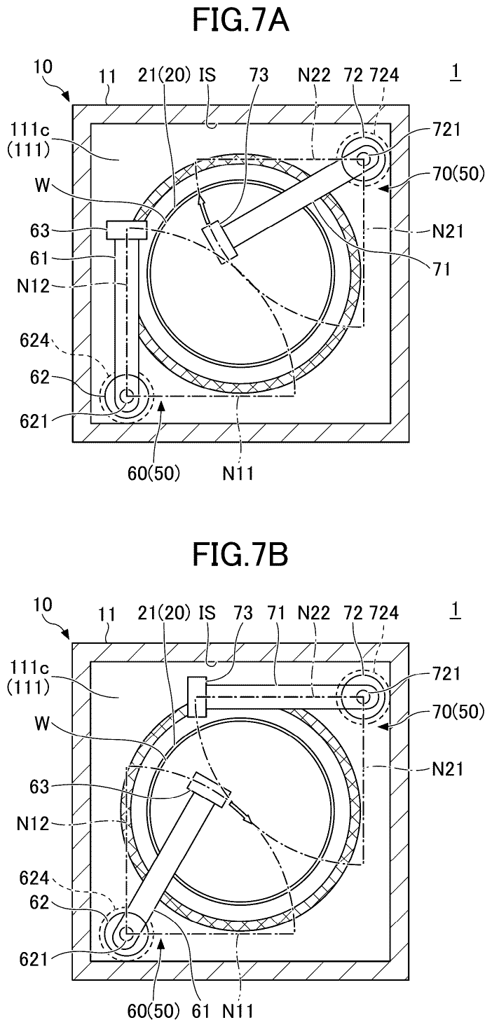

Then, as illustrated in FIG. 7A, the first nozzle 61 reaches the other first nozzle movement end N12, and starts an incoming movement from the other first nozzle movement end N12 toward the one first nozzle movement end N11. Meanwhile, as illustrated in FIG. 7B, the second nozzle 71 reaches the other second nozzle movement end N22 after the first head 63 reaches the other first nozzle movement end N12, and starts an incoming movement from the other second nozzle movement end N22 toward the one second nozzle movement end N21 at a timing later than the first nozzle 61. Because the second nozzle 71 has already passed through a position near the center of the substrate W upon the start of the incoming movement of the first nozzle 61, it is possible to avoid contact between the first nozzle 61 and the second nozzle 71.

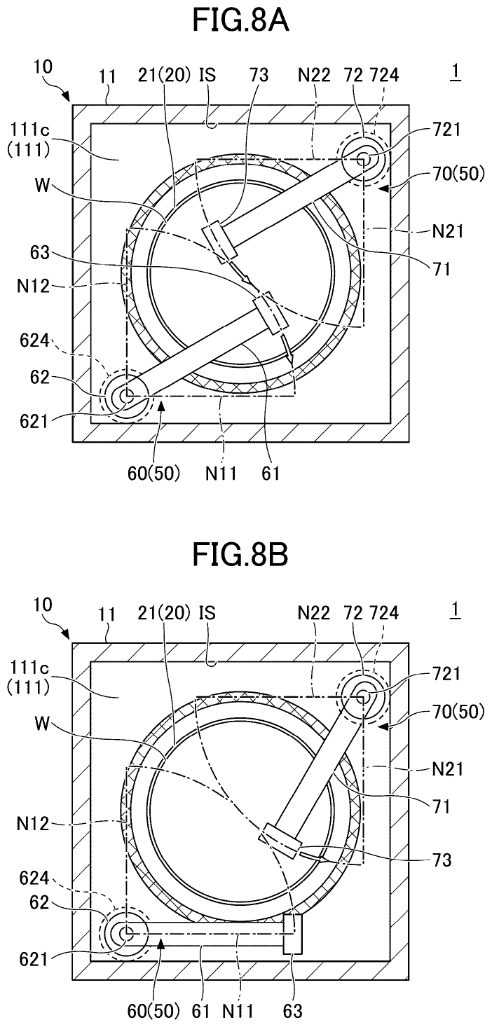

As illustrated in FIG. 8A, upon the incoming movement, the first head 63 reaches the position above the center of the substrate W, and passes through the center of the substrate W and reaches the one first nozzle movement end N11. As illustrated in FIG. 8B, the second head 73 reaches the position above the center of the substrate W after the first head 63 reaches there, and passes through the center of the substrate W and reaches the one second nozzle movement end N21.

By the above movements, the substrate-processing apparatus 1 can stably repeat the repeating movement of the first head 63, in which the discharge holes 633b pass over the center of the substrate W, and the repeating movement of the second head 73, in which the discharge hole 733b passes through the center of the substrate W. The movements of the first nozzle 61 and the second nozzle 71 are not limited to the above. For example, the substrate-processing apparatus 1 may be configured to alternately move the first nozzle 61 and the second nozzle 71. As an example, the controller 90 may be configured to perform the outgoing movement of the first nozzle 61 with the second nozzle 71 being in a standby state, and subsequently perform the outgoing movement of the second nozzle 71 with the first nozzle 61 being in a standby state. In this case, after the outgoing movement of the second nozzle 71, the controller 90 further performs the incoming movement of the first nozzle 61 with the second nozzle 71 being in a standby state, and subsequently performs the incoming movement of the second nozzle 71 with the first nozzle 61 being in a standby state.

As illustrated in FIG. 5, the controller 90 operates the gas supply 30 and the gas exhauster 40 together with the operation of the nozzle gas discharge mechanism 50, thereby starting supply of the process gases (adsorbing gas, reactive gas) and suction of the gas using the nozzle gas discharge mechanism 50 (step S5: (B)). No particular limitation is imposed on the timing of the operations of the gas supply 30 and the gas exhauster 40, which may be before or after the repeating movement of the first nozzle 61 and the second nozzle 71.

The discharge holes 633b of the first head 63 move along the first arc path, and form the adsorbing gas discharge region PR11 on the lower side in the vertical direction as illustrated in FIG. 3A, thereby adsorbing the adsorbing gas onto the rotating substrate W. Further, by forming the purge gas discharge region PR12 around the adsorbing gas discharge region PR11, the first head 63 can prevent spread of the adsorbing gas and readily control the adsorbing gas discharge region PR11. Then, by suctioning the gas in the suction region PR13 external of the discharge region PR12, the first head 63 can reduce the adsorbing gas remaining near the upper surface of the substrate W, and can prevent adhesion of the adsorbing gas to a region other than the first processing point region PR1 of the substrate W.

Meanwhile, the discharge hole 733b of the second head 73 moves along the second arc path, and forms the reactive gas discharge region PR21 on the lower side in the vertical direction as illustrated in FIG. 4A, thereby discharging the reactive gas, formed into a plasma, onto the rotating substrate W. Further, by forming the purge gas discharge region PR22 around the reactive gas discharge region PR21, the second head 73 can prevent spread of the reactive gas and readily control the reactive gas discharge region PR21. Then, by suctioning the gas in the suction region PR23 external of the discharge region PR22, the second head 73 can reduce the reactive gas remaining near the upper surface of the substrate W, and can prevent reaction of the reactive gas in a region other than the second processing point region PR2 of the substrate W.

As illustrated in FIG. 5, according to the substrate-processing method, the controller 90 determines whether or not the substrate processing ends in step S6. For example, the controller 90 monitors the target time set in the recipe or the like (or the process time set in accordance with the target film thickness or the like) and the actual operation time of the nozzle gas discharge mechanism 50. The controller 90 determines the end of the substrate processing when the actual operation time has reached the target time. The substrate-processing apparatus 1 may include, in the process chamber 10, an unillustrated film thickness measuring device configured to measure the film thickness, and determine the end of the substrate processing in accordance with the measured film thickness.

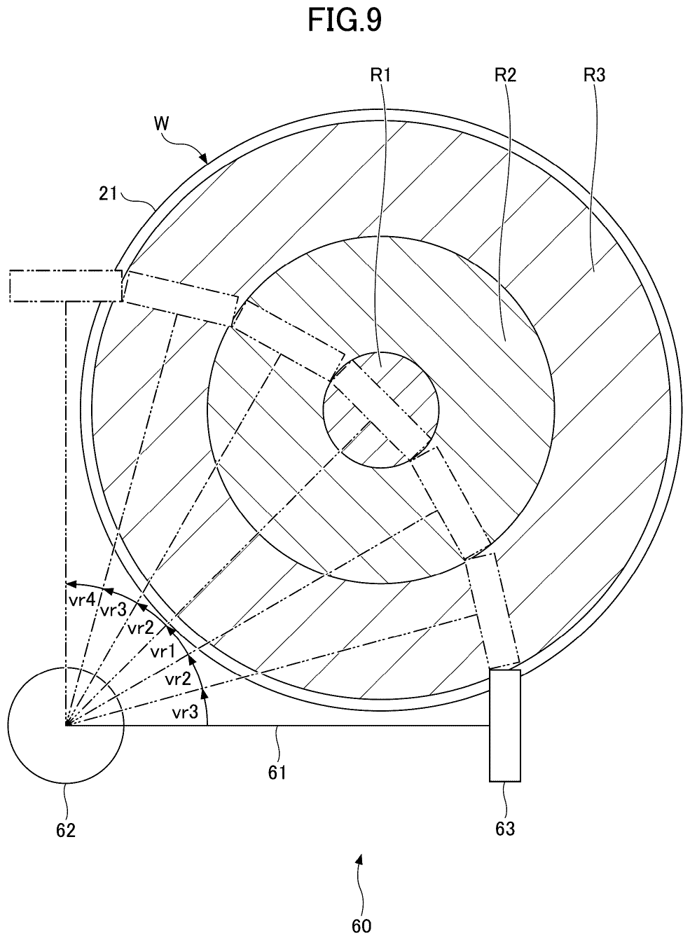

In addition, the controller 90 according to the embodiment performs control of changing a movement speed (swing speed) of the first nozzle gas discharge mechanism 60 and the second nozzle gas discharge mechanism 70 in accordance with the surface area of the substrate W in step S4 and step S5. The swing speed corresponds to a speed of a relative movement when the first nozzle gas discharge mechanism 60 and the second nozzle gas discharge mechanism 70 move relative to the rotating substrate W held by the substrate holder 20. The control of the swing speed (the speed of the relative movement) in the substrate-processing method will be described below in detail with reference to FIG. 9. In the following, the swing of the first nozzle gas discharge mechanism 60 will be described, and description of the second nozzle gas discharge mechanism 70 swinging in the same manner will be omitted.

When the surface of the substrate W is divided into multiple sections so as to have equally divided radii from the center of the substrate W in a radial outward direction, the surface areas of the sections are smaller at a center area and are larger on the outer edge side. In FIG. 9, the surface of the substrate W is divided into three sections (hereinafter the divided sections may also be referred to as a first section R1 to a third section R3 in the order from the center to the outer edge of the substrate W). The intervals of the first section R1 to the third section R3 are preferably set in accordance with the diameter of the substrate W. For example, when the diameter of the substrate W is 300 mm, the intervals of the first section R1 to the third section R3 may be 60 mm. Also, the interval of each section approximately coincides with the longitudinal length of the first head 63 and the second head 73. The number of the divided sections is not limited to three, but may be two or may be four or more.

The first section R1 has a regular circular shape at the center of the substrate W. The second section R2 is externally next to the first section R1 and has an annular shape around the first section R1. The third section R3 is externally next to the second section R2 and has an annular shape around the second section R2. In this case, a relation between the surface areas of the sections is as follows: the first section R1<the second section R2<the third section R3.

For film formation, it is usually required to keep constant the thickness of a film formed on the substrate W (i.e., increase in-plane uniformity). Therefore, the substrate-processing method according to the embodiment attempts to ensure in-plane uniformity in the substrate processing by supplying a large amount of the process gas toward the outer edge of the rotating substrate W and a small amount of the process gas toward the center of the rotating substrate W.

Specifically, the controller 90 sets the swing speed of the first nozzle gas discharge mechanism 60 to become slower in order from the first section R1 (at the center area) to the third section R3 (on the outer edge side). When the swing speed of the first nozzle gas discharge mechanism 60 is high, the discharge holes 633b of the first head 63 face the surface of the rotating substrate W in the circumferential direction for a short period of time. Therefore, the first head 63 can reduce the process gas supplied per unit area of the surface of the substrate W. Conversely, when the swing speed of the first nozzle gas discharge mechanism 60 is low, the discharge holes 633b of the first head 63 face the surface of the rotating substrate W in the circumferential direction for a long period of time. Therefore, the first head 63 can increase the process gas supplied per unit area of the surface of the substrate W.

In view of the above, the controller 90 sets the swing speed of the first nozzle gas discharge mechanism 60 to be as follows: a speed Vr1 in the first section R1>a speed Vr2 in the second section R2>a speed Vr3 in the third section R3. In other words, the swing speed (the speed of the relative movement) is set to be lower as the surface area of a section of the substrate W becomes larger, the section being faced by the discharge holes 633b. For example, the controller 90 may monitor the rotation angle of the first nozzle 61 in accordance with a signal of an unillustrated encoder of the first nozzle driver 62, and change the swing speed when the front end of the first head 63 in the rotation direction overlaps the boundary between the sections. In the example of FIG. 9, the boundary of each section changes by approximately 16° with the rotation base point of the first nozzle 61 being set as a reference. Therefore, the controller 90 may change the swing speed every 16° of the rotation angle of the first nozzle.

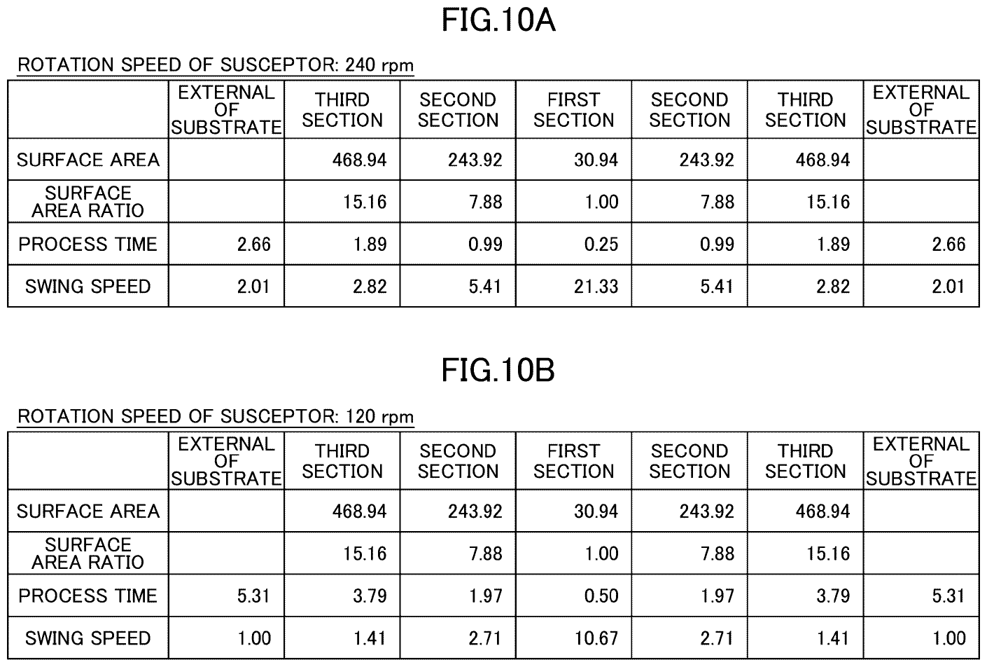

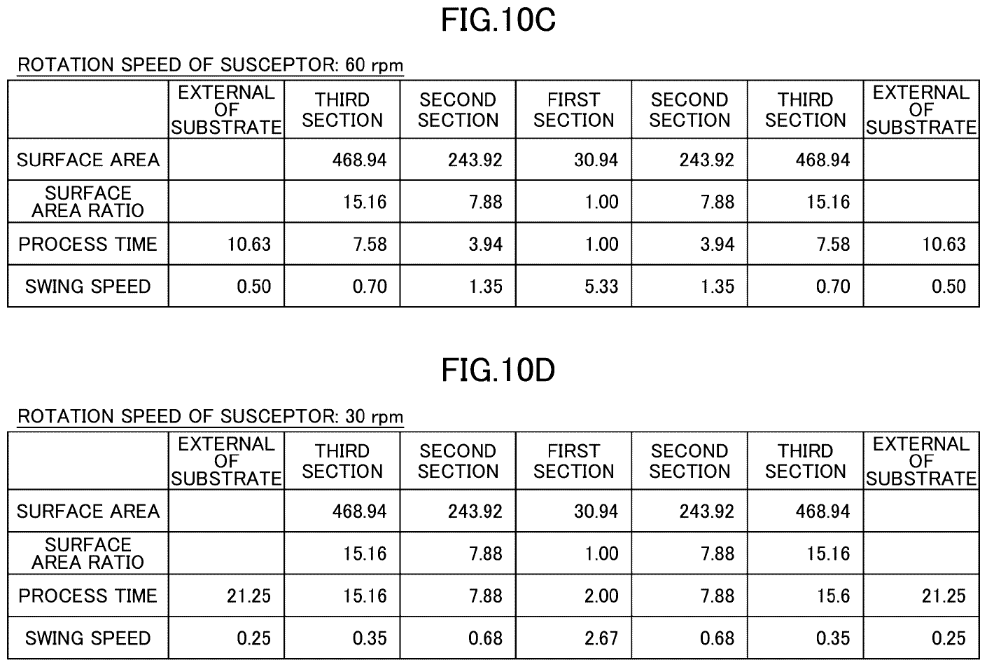

The controller 90 preferably sets the swing speed of the first nozzle gas discharge mechanism 60 in each section in accordance with the rotation speed of the susceptor 21 (substrate W). Next, the relation between the rotation speed of the susceptor 21 and the swing speed of the first nozzle gas discharge mechanism 60 will be described with reference to FIG. 10A and FIG. 10B. FIG. 10A to FIG. 10D illustrate examples in which the substrate W having a diameter of 300 mm as illustrated in FIG. 9 is equally divided into five sections (the third section R3, the second section R2, the first section R1, the second section R2, and the third section R3). In other words, FIG. 10A to FIG. 10D illustrate the surface areas when the intervals of the sections are each 60 mm. The length of the first nozzle 61 is 225 mm, which is 1.5 times the radius of the substrate W.

In FIG. 10A to FIG. 10D, the “SURFACE AREA RATIO” is a ratio of the sections with the first section R1 at the center of the substrate W being set as a reference (1.00). The “PROCESS TIME” is the time required to uniformly supply the process gas (i.e., adsorb the adsorbing gas) to the sections of the substrate W in accordance with the rotation speed of the susceptor 21. The “SWING SPEED” is an example of the swing speed of the first nozzle gas discharge mechanism 60 calculated based on the surface area ratio of the substrate W and the rotation speed of the susceptor 21. The “EXTERNAL OF SUBSTRATE” illustrates an example of the swing speed (a swing speed vr4 in FIG. 9) of the first nozzle gas discharge mechanism 60 external of the outer edge of the substrate W (the third section R3) during swing of the first nozzle gas discharge mechanism 60.

FIG. 10A illustrates the process time and the swing speed in the sections when the rotation speed of the susceptor 21 is set to 240 rpm. In this case, 0.25 seconds is required for the substrate W to rotate once when the first head 63 is positioned in the first section R1. Thus, the swing speed vr1 of the first nozzle gas discharge mechanism 60 is 21.33 rpm for ensuring that the first head 63 of the first section R1 faces the entire surface of the substrate W when the substrate W rotates once.

Similarly, when the swing speeds vr2 and vr3 of the first nozzle gas discharge mechanism 60 are calculated for other sections, the vr2 is 5.41 rpm and the vr3 is 2.82 rpm. In the second section R2 and the third section R3, the first head 63 faces each section twice when the first nozzle gas discharge mechanism 60 performs the outgoing movement once, and thus the swing speed can be halved in these sections. As a result, the first head 63 can reliably face (pass over) once the entire surface of the substrate W rotating at 240 rpm. However, the swing speed of the first nozzle gas discharge mechanism 60 is not limited to a value that enables the first head 63 to face the substrate W once. The swing speed of the first nozzle gas discharge mechanism 60 may be set to a value that enables the first head 63 to pass over the substrate W multiple times (e.g., twice to about 10 times). By passing through the substrate W multiple times, it is possible to increase the amount of the adsorbing gas adsorbed on the entire surface of the substrate W.

FIG. 10B illustrates the process time and the swing speed when the rotation speed of the susceptor 21 is set to 120 rpm. In this case, 0.5 seconds is required for the substrate W to rotate once when the first head 63 is positioned in the first section R1. Also, the swing speeds of the first nozzle gas discharge mechanism 60 in the sections are as follows: vr1=10.67 rpm, vr2=2.71 rpm, and vr3=1.41 rpm.

FIG. 10C illustrates the process time and the swing speed when the rotation speed of the susceptor 21 is set to 60 rpm. In this case, 1.00 second is required for the substrate W to rotate once when the first head 63 is positioned in the first section R1. Also, the swing speeds of the first nozzle gas discharge mechanism 60 in the sections are as follows: vr1=5.33 rpm, vr2=1.35 rpm, and vr3=0.70 rpm.

FIG. 10D illustrates the process time and the swing speed when the rotation speed of the susceptor 21 is set to 30 rpm. In this case, 2.00 seconds is required for the substrate W to rotate once when the first head 63 is positioned in the first section R1. Also, the swing speeds of the first nozzle gas discharge mechanism 60 in the sections are as follows: vr1=2.67 rpm, vr2=0.68 rpm, and vr3=0.35 rpm.

In this manner, by setting the swing speed of the first nozzle gas discharge mechanism 60 in each section in accordance with the rotation speed of the susceptor 21, the controller 90 can uniformly adsorb the adsorbing gas on the entire surface of the substrate W.

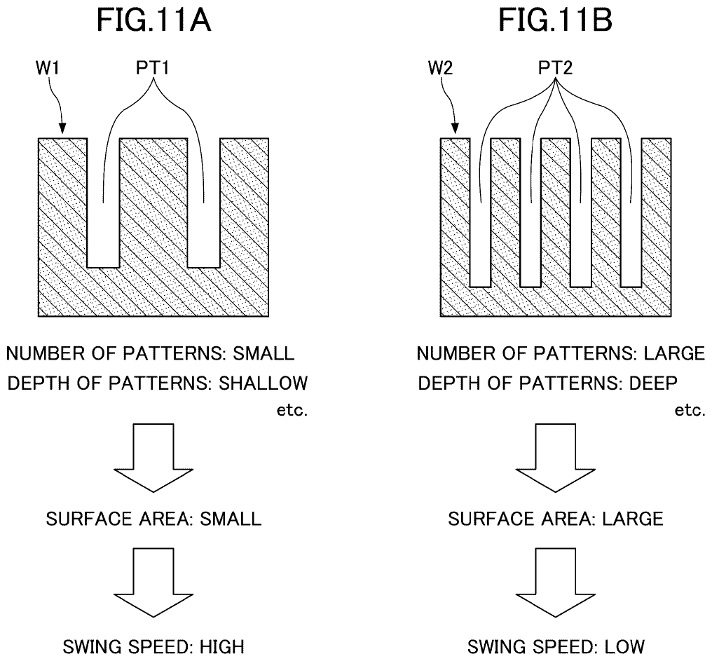

The surface area of each section of the substrate W is not limited to that calculated only from the area of the substrate W in a plan view. The surface area of each section of the substrate W also varies with a pattern (e.g., a trench, a via, and the like) of the semiconductor device formed on the surface. For example, as illustrated in FIG. 11A and FIG. 11B, the substrates W1 and W2 have patterns PT1 and PT2 having various numbers and depths. When the number of the patterns PT1 is small in the substrate W1 as illustrated in FIG. 11A, the surface area of the substrate W1 becomes small. Similarly, when the depth of each pattern PT1 in the substrate W1 is shallow, the surface area of the substrate W1 becomes small. Conversely, as illustrated in FIG. 11B, when the number of the patterns PT2 in the substrate W2 is large, the surface area of the substrate W2 becomes large. Similarly, when the depth of each pattern PT2 in the substrate W2 is deep, the surface area of the substrate W2 becomes large.

Therefore, the controller 90 preferably sets the swing speed of the first nozzle gas discharge mechanism 60 based on the surface areas of the patterns PT1 and PT2 of the substrates W1 and W2. The surface areas corresponding to the patterns PT1 and PT2 of the substrates W1 and W2 can be estimated, for example, based on design data and recipes of the patterns PT1 and PT2 stored in the memory 92 (see FIG. 1) and based on the time and number of the substrate processing. The controller 90 sets the swing speed of the first nozzle gas discharge mechanism 60 to be high when the estimated surface area of the substrate W is small. Conversely, the controller 90 sets the swing speed of the first nozzle gas discharge mechanism 60 to be low when the estimated surface area of the substrate W is large. Thus, the first nozzle gas discharge mechanism 60 can appropriately (uniformly) cause the adsorbing gas to be adsorbed in accordance with the surface areas of the various patterns PT1 and PT2.

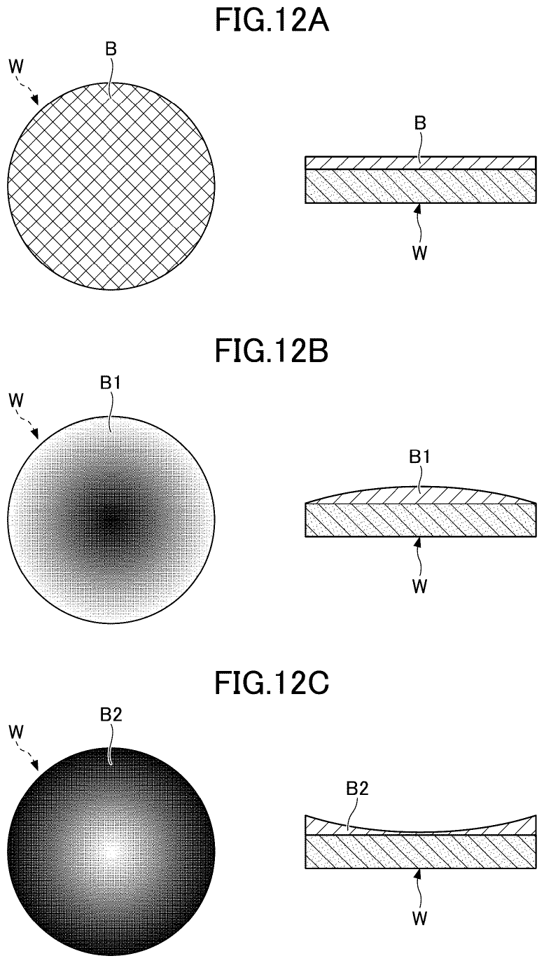

As the substrate-processing method, an example of controlling the swing speed of the first nozzle gas discharge mechanism 60 and the swing speed of the second nozzle gas discharge mechanism 70 so that the film thickness of a film B formed along the plane direction of the substrate W is constant as illustrated in FIG. 12A has been described above. However, the substrate-processing method is not limited to the substrate processing performed so as to make the film thickness constant. As illustrated in FIG. 12B and FIG. 12C, the substrate-processing method may control the swing speed of the first nozzle gas discharge mechanism 60 and the swing speed of the second nozzle gas discharge mechanism 70 so that a film B1 and a film B2 each having a varied film thickness are formed along the plane direction of the substrate W in accordance with the recipes.

For example, as illustrated in FIG. 12B, the substrate-processing method may form the dome-shaped film B1 having a large film thickness at the center area of the substrate W and a small film thickness on the outer edge side of the substrate W. As an example, the controller 90 causes the swing speed of the first nozzle gas discharge mechanism 60 and the swing speed of the second nozzle gas discharge mechanism 70 to be low at the center area and high on the outer edge side. Further, the controller 90 adjusts the speed of the substrate W in each section in accordance with the surface area of a section of the substrate W, the section being faced by the nozzle gas discharge mechanism 50. Thus, the film B1 having the target shape can be formed with high accuracy.

Also, for example, as illustrated in FIG. 12C, the substrate-processing method may form the concave (bowl-shaped) film B2 having a small film thickness at the center area of the substrate W and a large film thickness on the outer edge side of the substrate W. As an example, the controller 90 causes the swing speed of the first nozzle gas discharge mechanism 60 and the swing speed of the second nozzle gas discharge mechanism 70 to be high at the center area and low on the outer edge side. In this case, the controller 90 adjusts the speed of the substrate W in each section in accordance with the surface area of a section of the substrate W, the section being faced by the nozzle gas discharge mechanism 50. Thus, the film B2 having the target shape can be formed with high accuracy.

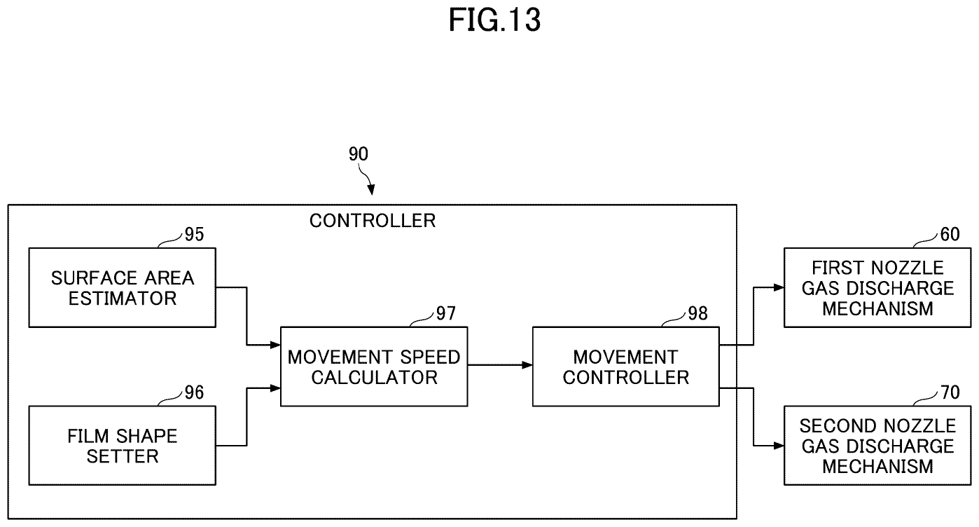

In order to control the speeds of the first nozzle gas discharge mechanism 60 and the second nozzle gas discharge mechanism 70 as described above, the controller 90 includes a surface area estimator 95, a film shape setter 96, a movement speed calculator 97, and a movement controller 98, as illustrated in FIG. 13, for example.

The surface area estimator 95 is configured to estimate the surface areas of the multiple divided sections of the substrate W. As described above, the surface area of each section is the surface area thereof in the entire circumferential direction calculated in consideration of the number, depth, and the like of the patterns formed at the substrate W. The surface area estimator 95 can estimate the surface area of each section with high accuracy in accordance with the set recipe and the number of divided sections. The surface area estimator 95 outputs the estimated surface area to the movement speed calculator 97.

The film shape setter 96 is a functional component configured to set the target shape of a film to be formed, as illustrated in FIG. 12A to FIG. 12C. For example, the film shape setter 96 enables setting the target shape of the film to be formed in accordance with a selection operation or an input operation performed by a user of the substrate-processing apparatus 1. Once the target shape of the film is set by the user, the film shape setter 96 outputs the set data to the movement speed calculator 97.

The movement speed calculator 97 is configured to calculate the swing speed of the first nozzle gas discharge mechanism 60 for each section and the swing speed of the second nozzle gas discharge mechanism 70 for each section, in accordance with the received data, i.e., the surface area of each section of the substrate W and the target shape of a film. The movement speed calculator 97 may set the swing speed of the first nozzle gas discharge mechanism 60 for each section and the swing speed of the second nozzle gas discharge mechanism 70 for each section so as to be different. This enables appropriate control in accordance with the film to be formed. For example, the swing speed of the second nozzle gas discharge mechanism 70 is controlled to be high at a site where oxidation of the film is to be prevented, and the swing speed of the second nozzle gas discharge mechanism 70 is controlled to be low at a site where oxidation of the film is to be promoted.

The movement controller 98 is configured to control the movement of the first nozzle gas discharge mechanism 60 in accordance with the calculated swing speed of the first nozzle gas discharge mechanism 60, and control the movement of the second nozzle gas discharge mechanism 70 in accordance with the calculated swing speed of the second nozzle gas discharge mechanism 70.

As described above, the substrate-processing method according to the embodiment changes the swing speed of the first nozzle gas discharge mechanism 60 and the swing speed of the second nozzle gas discharge mechanism 70 in accordance with the surface area of the substrate W. This enables appropriate adjustment of the substrate processing on the surface of the substrate W. For example, the substrate-processing method can make constant the thickness of the film on the substrate W (i.e., increase in-plane uniformity) and attempt to increase the quality of the resulting film.

The substrate-processing apparatus 1 and the substrate-processing method are not limited to the above embodiments, and various modified examples thereof are possible. As an example, the nozzle gas discharge mechanism 50 of the substrate-processing apparatus 1 is not limited to the configuration including only the first nozzle gas discharge mechanism 60 and the second nozzle gas discharge mechanism 70, and may include three or more nozzle gas discharge mechanisms. Even in the case of including three or more nozzle gas discharge mechanisms (e.g., nozzle gas discharge mechanisms for adsorbing gas, reactive gas, and etching gas), the swing speed can be set in accordance with the surface area of each section of the substrate W.

Further, the controller 90 is not limited to the configuration of changing the swing speed step by step for each section of the substrate W, and may smoothly change the swing speed along the radial direction of the substrate W. For example, in accordance with set speed-changing information, the controller 90 gradually increases the swing speed from the outer edge of the substrate W toward the center thereof, and after reaching the center of the substrate W, gradually decreases the swing speed toward the outer edge of the substrate W.

Further, no particular limitation is imposed on the repeated movement range (angle) of the first nozzle gas discharge mechanism 60 or the second nozzle gas discharge mechanism 70 as long as the first head 63 and the second head 73 can move at least between the center and the outer edge of the substrate W. In the case of repeatedly moving between the center and the outer edge of the substrate W, the swing speed on the outer edge side may be controlled to be lower.

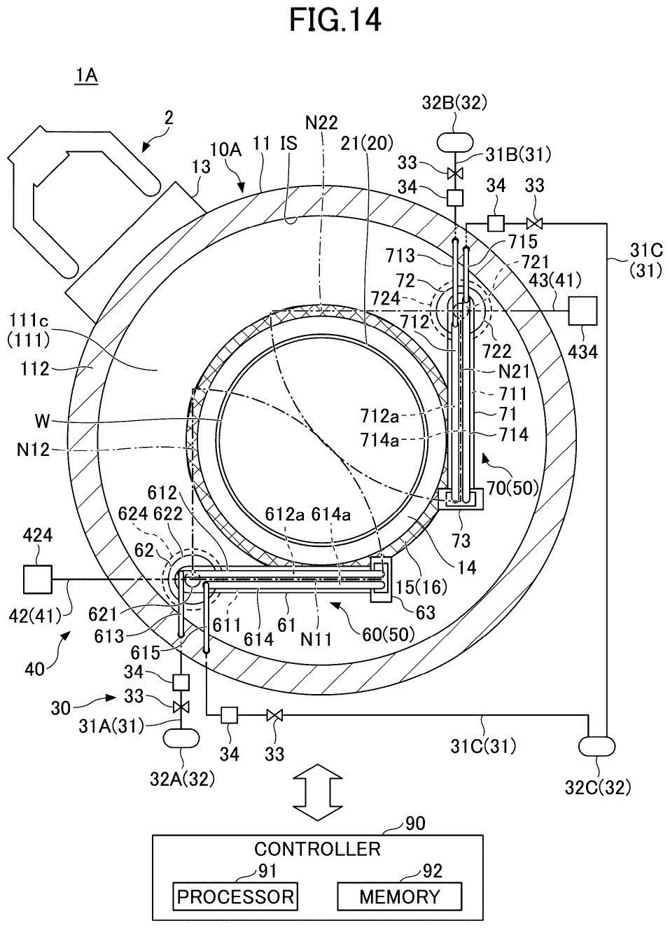

Further, as in a modified example as illustrated in FIG. 14, a substrate-processing apparatus 1A may have a cylindrical process chamber 10A instead of the rectangular process chamber 10. The configurations of the substrate holder 20, the gas supply 30, the gas exhauster 40, and the nozzle gas discharge mechanism 50 of the substrate-processing apparatus 1A are approximately the same as those of the substrate-processing apparatus 1. By applying the cylindrical process chamber 10A, the substrate-processing apparatus 1A can prevent retention or the like of gas in the process chamber 10A and can make the gas flow more uniform, and uniformity of the substrate processing can be further increased.

Further, the nozzle gas discharge mechanism 50 of the substrate-processing apparatuses 1 and 1A may be configured without including the purge gas dischargers 634 and 734, or may be configured without including the gas suction sections 635 and 735.

The technical ideas and effects of the present disclosure described in the above embodiments will be described below.

A first aspect of the present disclosure is a substrate-processing method for processing the substrate W, the substrate-processing method including: (A) holding the substrate W by the substrate holder 20 in the process chamber 10 and rotating the substrate W; (B) discharging gas from the discharge holes 633b and 733b of the nozzle gas discharge mechanism 50 toward the substrate W held by the substrate holder 20; and (C) moving the nozzle gas discharge mechanism 50 relative to the substrate W in a direction parallel to the surface of the substrate W held by the substrate holder 20 so that the discharge holes 633b and 733b pass over the center of the substrate W, in which in (C), the speed of the relative movement of the nozzle gas discharge mechanism 50 is changed in accordance with the surface area of a section of the substrate W, the section being faced by the discharge holes 633b and 733b.

According to the above description, the substrate-processing method can perform the substrate processing on the surface of the substrate W with high accuracy by changing the speed of the relative movement of the nozzle gas discharge mechanism 50 in accordance with the surface area of the substrate W. That is, the substrate-processing method enables the discharge holes 633b and 733b of the nozzle gas discharge mechanism 50 to face the surface of the rotating substrate W in accordance with the surface area of the substrate W for an appropriate period of time. Thus, the substrate-processing method can supply a target amount of gas from the nozzle gas discharge mechanism 50 to the surface of the substrate W with high accuracy, thereby increasing the quality of the substrate processing.

Further, in (C), the speed of the relative movement is set to be lower as the surface area of a section of the substrate W becomes larger, the section being faced by the discharge holes 633b and 733b. Thereby, the substrate-processing method can stably supply gas even to a section having a large surface area.

Further, in (C), the speed of the relative movement on the outer edge side of the substrate W is set to be lower than the speed of the relative movement at the center area of the substrate W. Because the surface area of the outer edge side of the substrate W is larger than the surface area at the center area of the substrate W, the substrate-processing method can supply a sufficient amount of gas to the outer edge side of the substrate W by decreasing the relative speed of the nozzle gas discharge mechanism 50.

In (C), the speed of the relative movement is set in accordance with the surface area of the substrate W including the patterns PT1 and PT2 formed at the surface of the substrate W. By considering the patterns PT1 and PT2 for calculation of the surface area of the substrate W, the substrate-processing method can stably supply gas upon the substrate processing for the patterns PT1 and PT2 of the substrate W.

In (C), the surface of the substrate W is divided into multiple sections, and the speed of the relative movement is set for each of the multiple sections. Thereby, the substrate-processing method can readily adjust the relative speed of the nozzle gas discharge mechanism 50 in accordance with each of the sections.

In (C), the speed of the relative movement is set in accordance with the target shape of the film to be formed on the surface of the substrate W. Thereby, the substrate-processing method can readily form the film having the target shape on the surface of the substrate W.

Further, the nozzle gas discharge mechanism 50 includes the first nozzle gas discharge mechanism 60 and the second nozzle gas discharge mechanism 70 for discharging gas to the substrate W held by the substrate holder 20. In (C), the first nozzle gas discharge mechanism 60 and the second nozzle gas discharge mechanism 70 are caused to swing independently of each other while the substrate W is being rotated in (A). By using the first nozzle gas discharge mechanism 60 and the second nozzle gas discharge mechanism 70, the substrate-processing method can perform various processes, such as supplying the reactive gas to the substrate W after supplying the adsorbing gas to the substrate W.

The first nozzle gas discharge mechanism 60 includes: the first nozzle 61 extending in the process chamber 10; the first nozzle driver 62 provided at the base end of the first nozzle 61 and configured to swing the first nozzle 61; and the first head 63 provided at the tip end of the first nozzle 61 and configured to discharge a first process gas. The second nozzle gas discharge mechanism 70 includes: the second nozzle 71 extending in the process chamber 10; the second nozzle driver 72 provided at the base end of the second nozzle 71 and configured to swing the second nozzle 71; and the second head 73 provided at the tip end of the second nozzle 71 and configured to discharge a second process gas. Thereby, it is possible to smoothly supply gases to the substrate W from the first nozzle gas discharge mechanism 60 and the second nozzle gas discharge mechanism 70.

In (C), the first head 63 and the second head 73 are caused to repeatedly move over at least a range between the center of the substrate W held by the substrate holder 20 and the outer edge of the substrate W. Thereby, the substrate-processing method can uniformly perform the substrate processing by causing the gas discharge holes 633b and 733b to face the entire surface of the substrate W.

The substrate-processing apparatuses 1 and 1A for processing the substrate W include: the process chamber 10 configured to house the substrate W; the substrate holder 20 configured to hold the substrate W in the process chamber 10 and rotate the substrate W; the nozzle gas discharge mechanism 50 including the discharge holes 633b and 733b for discharging gas toward the substrate W held by the substrate holder 20 and being movable relative to the substrate W in a direction parallel to the surface of the substrate W held by the substrate holder 20 so that the discharge holes 633b and 733b pass over the center of the substrate W; and the controller 90 configured to control the nozzle gas discharge mechanism 50, in which the controller 90 changes the speed of the relative movement of the nozzle gas discharge mechanism 50 in accordance with the surface area of a section of the substrate W, the section being faced by the discharge holes 633b and 733b. Even in this case, the substrate-processing apparatuses 1 and 1A can perform the substrate processing on the surface of the substrate W with high accuracy.

The substrate-processing method and the substrate-processing apparatuses 1 and 1A according to the embodiment disclosed herein are illustrative in all respects and are not limiting. The embodiments can be modified and improved in various ways without departing from the scope of claims recited and the subject matters thereof. The matters described in the above embodiments can take other configurations to an extent without involving contradiction and may be combined to an extent without involving contradiction.

According to one embodiment, it is possible to perform substrate processing on the surface of a substrate with high accuracy.

What is claimed is:

1. A substrate-processing method for processing a substrate, the substrate-processing method comprising:
(A) holding the substrate by a substrate holder in a process chamber and rotating the substrate;
(B) discharging gas from a discharge hole of a nozzle gas discharge mechanism toward the substrate held by the substrate holder; and
(C) moving the nozzle gas discharge mechanism relative to the substrate in a direction parallel to a surface of the substrate held by the substrate holder so that the discharge hole passes over a center of the substrate, wherein
in (C), a speed of a relative movement of the nozzle gas discharge mechanism is changed in accordance with a surface area of a section of the substrate, the section being faced by the discharge hole.

2. The substrate-processing method according to claim 1, wherein
in (C), the speed of the relative movement is set to be lower as a surface area of the section becomes larger.

3. The substrate-processing method according to claim 2, wherein
in (C), the speed of the relative movement on an outer edge side of the substrate is set to be lower than the speed of the relative movement at a center area of the substrate.

4. The substrate-processing method according to claim 2, wherein
in (C), the speed of the relative movement is set in accordance with a surface area of the substrate, the surface area including a surface area of a pattern formed at the surface of the substrate.

5. The substrate-processing method according to claim 2, wherein
in (C), the surface of the substrate is divided into multiple sections, and the speed of the relative movement is set for each of the multiple sections.

6. The substrate-processing method according to claim 1, wherein
in (C), the speed of the relative movement is set in accordance with a target shape of a film to be formed on the surface of the substrate.

7. The substrate-processing method according to claim 1, wherein
the nozzle gas discharge mechanism includes a first nozzle gas discharge mechanism and a second nozzle gas discharge mechanism that are configured to discharge the gas to the substrate held by the substrate holder, wherein
in (C), the first nozzle gas discharge mechanism and the second nozzle gas discharge mechanism are caused to swing independently of each other while the substrate is being rotated in (A).

8. The substrate-processing method according to claim 7, wherein
the first nozzle gas discharge mechanism includes
a first nozzle extending in the process chamber,
a first nozzle driver provided at a base end of the first nozzle and configured to swing the first nozzle, and
a first head provided at a tip end of the first nozzle and configured to discharge a first process gas as the gas, and
the second nozzle gas discharge mechanism includes
a second nozzle extending in the process chamber,
a second nozzle driver provided at a base end of the second nozzle and configured to swing the second nozzle, and
a second head provided at a tip end of the second nozzle and configured to discharge a second process gas as the gas.

9. The substrate-processing method according to claim 8, wherein
in (C), the first head and the second head are caused to repeatedly move over at least a range between the center of the substrate held by the substrate holder and an outer edge of the substrate.

10. A substrate-processing apparatus for processing a substrate, the substrate-processing apparatus comprising:
a process chamber configured to house the substrate;
a substrate holder configured to hold the substrate in the process chamber and rotate the substrate;
a nozzle gas discharge mechanism including a discharge hole for discharging gas toward the substrate held by the substrate holder and being movable relative to the substrate in a direction parallel to a surface of the substrate held by the substrate holder so that the discharge hole passes over a center of the substrate; and
a controller configured to control the nozzle gas discharge mechanism, wherein
the controller includes
a processor, and
a memory storing one or more programs, which when executed, cause the processor to:
change a speed of a relative movement of the nozzle gas discharge mechanism in accordance with a surface area of a section of the substrate, the section being faced by the discharge hole.
